(19) United States
(12) Patent Application Publication
(10) Pub. No.: US 2024/0324387 A1
(43) Pub. Date: Sep. 26, 2024

(54) DISPLAY APPARATUS

(71) Applicant: SAMSUNG DISPLAY CO., LTD., YONGIN-SI (KR)

(72) Inventors: Seokgyu Yoon, Yongin-si (KR); Soungwook Kim, Yongin-si (KR); Hwasook Ryu, Yongin-si (KR); Hyejin Jung, Yongin-si (KR); Kunwook Cho, Yongin-si (KR)

(21) Appl. No.: 18/603,478

(22) Filed: Mar. 13, 2024

(30) Foreign Application Priority Data
Mar. 24, 2023 (KR) 10-2023-0039101
Jul. 13, 2023 (KR) 10-2023-0091346

(51) Int. Cl. H10K 59/38; H10K 59/40; H10K 102/10

(52) U.S. Cl. CPC H10K 59/38; H10K 59/40; H10K 2102/101

(57) ABSTRACT

A display apparatus includes a substrate including an emission area and a sensing area, a plurality of light-emitting devices disposed on the substrate and overlapping the emission area, and a plurality of light-receiving devices disposed on the substrate and overlapping the sensing area. Each of the plurality of light-emitting devices includes a pixel electrode, an emission layer disposed on the pixel electrode, and an opposite electrode disposed on the emission layer. Each of the plurality of light-receiving devices includes a sensing electrode, an active layer disposed on the sensing electrode, and an opposite electrode disposed on the active layer. At least one of the plurality of sensing electrodes has a structure that is different from a stacked structure of the pixel electrode, and the sensing electrode includes a transparent conductive layer.

### CROSS-REFERENCE TO RELATED APPLICATIONS

This application claims priority under 35 U.S.C. § 119 to Korean Patent Application No. 10-2023-0039101 filed on Mar. 24, 2023, and Korean Patent Application No. 10-2023-0091346 filed on Jul. 13, 2023, the disclosures of which are incorporated by reference herein in their entireties.

### TECHNICAL FIELD

Embodiments of the present disclosure relate to a structure of a display apparatus.

### DISCUSSION OF RELATED ART

Generally, a display apparatus includes light-emitting devices such as, for example, organic light-emitting diodes and thin-film transistors disposed on a substrate, and operates by way of the light-emitting devices emitting light.

For example, each of pixels of the display apparatus may have a light-emitting device, such as an organic light-emitting diode, in which an intermediate layer including an emission layer is disposed between a pixel electrode and an opposite electrode. Generally, the display apparatus controls whether each pixel emits light, or a degree of light emission through the thin-film transistor electrically connected to the pixel electrode. Some layers included in the intermediate layer of the light-emitting device are commonly provided for the plurality of light-emitting devices.

### SUMMARY

Embodiments of the present disclosure include a display apparatus including a light-receiving device having increased detection performance. However, embodiments are not limited thereto.

According to an embodiment, a display apparatus includes a substrate including an emission area and a sensing area, a plurality of light-emitting devices disposed on the substrate and overlapping the emission area, and a plurality of light-receiving devices disposed on the substrate and overlapping the sensing area. Each of the plurality of light-emitting devices includes a pixel electrode, an emission layer disposed on the pixel electrode, and an opposite electrode disposed on the emission layer. Each of the plurality of light-receiving devices includes a sensing electrode, an active layer disposed on the sensing electrode, and an opposite electrode disposed on the active layer. At least one of the plurality of sensing electrodes has a structure that is different from a stacked structure of the pixel electrode, and the sensing electrode includes a first transparent conductive layer.

The pixel electrode may include a transflective electrode including a second transparent conductive layer and a transflective metal layer.

The transflective metal layer may include at least one of Ag, Al, Mg, Li, Ca, Cu, LiF/Ca, LiF/Al, MgAg, and CaAg.

The sensing electrode may include a transparent electrode including a transparent conductive layer, and the transparent conductive layer may include transparent conductive oxide (TCO).

Each of the plurality of light-receiving devices may have a non-cavity structure.

Each of the plurality of sensing electrodes may have a same thickness as each other.

The plurality of light-receiving devices may include a first light-receiving device, a second light-receiving device, and a third light-receiving device spaced apart from each other.

The active layer included in each of the first light-receiving device, the second light-receiving device, and the third light-receiving device may include a same material as each other.

The display apparatus may further include a first light-receiving color filter disposed on the first light-receiving device, a second light-receiving color filter disposed on the second light-receiving device, and a third light-receiving color filter disposed on the third light-receiving device. The first light-receiving color filter, the second light-receiving color filter, and the third light-receiving color filter may include different materials from each other.

The first light-receiving color filter may be a red color filter that transmits light of a wavelength band of about 600 nm to about 750 nm, the second light-receiving color filter may be a green color filter that transmits light of a wavelength band of about 495 nm to about 600 nm, and the third light-receiving color filter may be a blue color filter that transmits light of a wavelength band of about 380 nm to about 495 nm.

The plurality of light-emitting devices may include a first light-emitting device that emits red light, a second light-emitting device that emits green light, and a third light-emitting device that emits blue light. A first color filter disposed on the first light-emitting device includes a same material as the first light-receiving color filter, a second color filter disposed on the second light-emitting device includes a same material as the second light-receiving color filter, and a third color filter disposed on the third light-emitting device includes a same material as the third light-receiving color filter.

The display apparatus may further include a fourth light-receiving device spaced apart from the first light-receiving device, the second light-receiving device, and the third light-receiving device, and a fourth light-receiving color filter disposed on the fourth light-receiving device.

The fourth light-receiving color filter may transmit near-infrared rays of a wavelength band of about 750 nm to about 1000 nm.

The active layer included in the fourth light-receiving device may include a same material as the active layers included in the first light-receiving device, the second light-receiving device, and the third light-receiving device.

At least one of the plurality of sensing electrodes may include a main sensing electrode and a sub-sensing electrode disposed on the main sensing electrode. The main sensing electrode may include a same structure and a same material as the pixel electrode, and the sub-sensing electrode may include a transparent electrode including a third transparent conductive layer.

Each of the plurality of light-receiving devices may have a cavity structure.

The sub-sensing electrode may include transparent conductive oxide (TCO).

A thickness of the sub-sensing electrode may be proportional to a wavelength of light transmitted by a light-receiving color filter disposed on each sensing electrode.

The display apparatus may further include a common layer disposed between the sensing electrode and the active layer and between the pixel electrode and the emission layer.

A sum of a thickness of the common layer and a thickness of the sub-sensing electrode may correspond to a primary cavity distance or a secondary cavity distance of light transmitted by a light-receiving color filter disposed on each sensing electrode.

The display apparatus may further include an optical auxiliary layer disposed between the common layer and the active layer. A sum of a thickness of the common layer and a thickness of the optical auxiliary layer may correspond to a primary cavity distance or a secondary cavity distance of light transmitted by a light-receiving color filter disposed on each sensing electrode.

### BRIEF DESCRIPTION OF THE DRAWINGS

The above and other features of the present disclosure will become more apparent by describing in detail embodiments thereof with reference to the accompanying drawings, in which:

FIG. 1 is a schematic plan view of a portion of a display apparatus according to an embodiment;

FIG. 2 is an equivalent circuit diagram of a pixel circuit electrically connected to a light-emitting device included in a pixel of the display apparatus of FIG. 1;

FIG. 3 is a schematic cross-sectional view of a display apparatus according to an embodiment;

FIG. 4 is a schematic plan view of a portion of a display apparatus according to an embodiment;

FIG. 5 is a schematic cross-sectional view of a portion of a display apparatus according to an embodiment;

FIG. 6 is a schematic conceptual view of a portion of a display apparatus according to an embodiment;

FIG. 7 is a schematic cross-sectional view of a portion of a display apparatus according to an embodiment; and

FIG. 8 is a schematic conceptual view of a portion of a display apparatus according to an embodiment.

### DETAILED DESCRIPTION

Embodiments of the present disclosure will be described more fully hereinafter with reference to the accompanying drawings. Like reference numerals may refer to like elements throughout the accompanying drawings.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that the terms “first,” “second,” “third,” etc. are used herein to distinguish one element from another, and the elements are not limited by these terms. Thus, a “first” element in an embodiment may be described as a “second” element in another embodiment.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

When a certain embodiment may be implemented differently, a specific process order may be performed differently from the described order. For example, two consecutively described processes may be performed substantially at the same time or performed in an order opposite to the described order.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

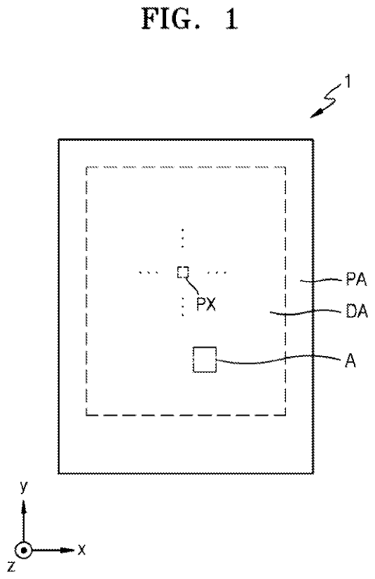

FIG. 1 is a schematic plan view of a portion of a display apparatus 1 according to an embodiment.

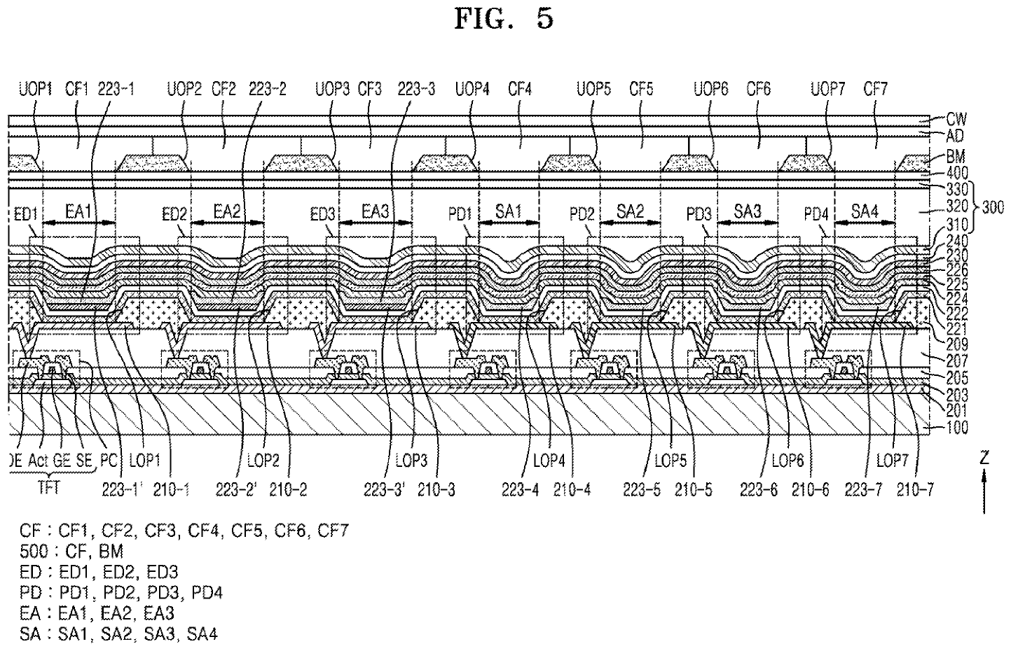

As illustrated in FIG. 1, the display apparatus 1 may include a display area DA in which a plurality of pixels PX are disposed, and a peripheral area PA disposed outside of the display area DA. In an embodiment, the peripheral area PA may entirely surround the display area DA. For example, a substrate 100 (see FIG. 5) included in the display apparatus 1 may have the display area DA and the peripheral area PA.

Each of the pixels PX of the display apparatus 1 denotes a minimum unit that display an image, and the display apparatus 1 may display a desired image through a combination of the plurality of pixels PX. In an embodiment, each pixel PX may emit light of a predetermined color, and the display apparatus 1 may display a desired image by using light emitted from the pixels PX. For example, each pixel PX may emit red light, green light, or blue light. Each pixel PX may include a light-emitting device, such as, for example, an organic light-emitting diode. The pixel PX may be connected to a pixel circuit including, for example, a thin-film transistor TFT, a storage capacitor, etc.

The display area DA may have, for example, a polygonal shape including a quadrangular shape as illustrated in FIG. 1. For example, the display area DA may have a rectangular shape having a horizontal length that is greater than a vertical length, a rectangular shape having a horizontal length that is less than a vertical length, or a square shape. Alternatively, the display area DA may have various shapes such as, for example, an oval shape or a circular shape.

The peripheral area PA may be a non-display area in which pixels PX are not disposed and an image is not displayed. A driver, etc. that provides an electrical signal or a power supply to the pixels PX may be disposed in the peripheral area PA. Pads to which various electronic elements or printed circuit boards may be electrically connected may be disposed in the peripheral area PA. The pads may be spaced apart from each other and may be electrically connected to the printed circuit board or an integrated circuit device.

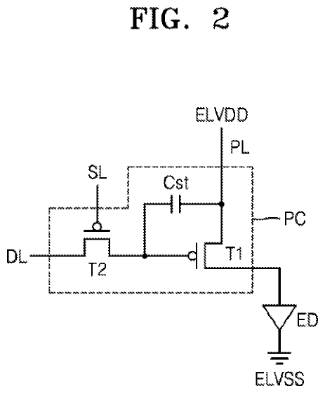

FIG. 2 is an equivalent circuit diagram of a pixel circuit PC electrically connected to a light-emitting device ED included in a pixel of the display apparatus 1 of FIG. 1.

The pixel circuit PC may include a first transistor T1, a second transistor T2, and a storage capacitor Cst. The second transistor T2, which is a switching transistor, may be connected to a scan line SL and a data line DL and may be turned on by a switching signal that is input from the scan line SL and configured to transmit a data signal that is input from the data line DL to the first transistor T1. The storage capacitor Cst may have one end electrically connected to the second transistor T2 and the other end electrically connected to a driving voltage line PL, and may store a voltage corresponding to a difference between a voltage received from the second transistor T2 and a driving power voltage ELVDD supplied to the driving voltage line PL.

The first transistor T1, which is a driving transistor, may be connected to the driving voltage line PL and the storage capacitor Cst and may be configured to control a magnitude of a driving current flowing from the driving voltage line PL to the light-emitting device ED according to a value of the voltage stored in the storage capacitor Cst. The light-emitting device ED may emit light having a certain brightness, according to the driving current. An opposite electrode of the light-emitting device ED may receive an electrode power voltage ELVSS.

FIG. 2 illustrates that the pixel circuit PC may include two transistors and one capacitor. However, the disclosure is not limited thereto. For example, the number of transistors and the number of storage capacitors may be variously modified according to the design of the pixel circuit PC.

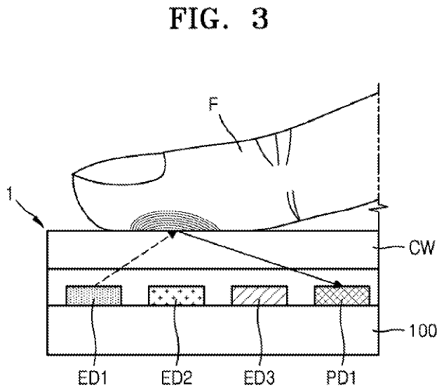

FIG. 3 is a schematic cross-sectional view of the display apparatus 1 according to an embodiment.

Referring to FIG. 3, the display apparatus 1 according to an embodiment may include a first light-emitting device ED1, a second light-emitting device ED2, a third light-emitting device ED3, and a first light-receiving device PD1. The first light-emitting device ED1, the second light-emitting device ED2, and the third light-emitting device ED3 may emit different colored light from one another. For example, the first light-emitting device ED1 may emit red light, the second light-emitting device ED2 may emit green light, and the third light-emitting device ED3 may emit blue light.

As illustrated in FIG. 3, the display apparatus 1 may have a function of sensing an object in contact with a cover window CW, for example, a fingerprint of a finger F. At least a portion of reflection light that is emitted from at least one of the first to third light-emitting devices ED1 to ED3 and reflected from a fingerprint F of a user may be incident again into the first light-receiving device PD1, and thus, the first light-receiving device PD1 may detect the reflection light. For example, the red light emitted by the first light-emitting device ED1 may be reflected by an object in contact with the cover window CW, and re-incident into the first light-receiving device PD1, and thus, the first light-receiving device PD1 may detect the re-incident red light.

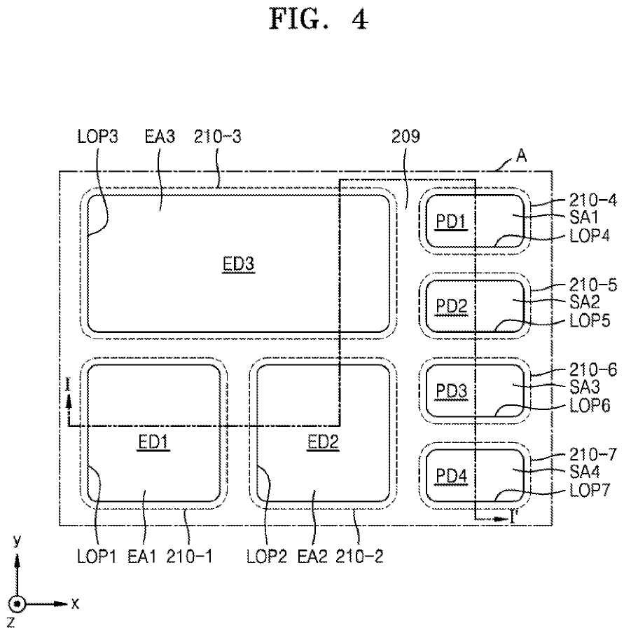

FIG. 4 is a schematic plan view of a portion of the display apparatus 1 according to an embodiment. For example, FIG. 4 is a schematic enlarged plan view of a region A of FIG. 1. FIG. 4 is a plan view showing elements on a bank layer 209.

As illustrated in FIG. 4, the display apparatus 1 may include a plurality of light-emitting devices and a plurality of light-receiving devices. The plurality of light-emitting devices may include a first light-emitting device ED1, a second light-emitting device ED2, and a third light-emitting device ED3, and the plurality of light-receiving devices may include a first light-receiving device PD1, a second light-receiving device PD2, a third light-receiving device PD3, and a fourth light-receiving device PD4. The first to third light-emitting devices ED1 to ED3 may emit light of different colors from one another. For example, the first light-emitting device ED1 may emit red light, the second light-emitting device ED2 may emit green light, and the third light-emitting device ED3 may emit blue light. The red light may be light in a wavelength band of about 600 nm to about 780 nm, the green light may be light in a wavelength band of about 495 nm to about 600 nm, and the blue light may be light in a wavelength band of about 380 nm to about 495 nm.

The first to third light-receiving devices PD1 to PD3 may sense an object by detecting light emitted by the first to third light-emitting devices ED1 to ED3 and reflected by the object. The fourth light-receiving device PD4 may sense an object by detecting light emitted by a near-infrared emission portion and reflected by the object. The near-infrared emission portion may emit near-infrared rays of a wavelength band of about 750 nm to about 1000 nm. The near-infrared emission portion may include, for example, a piezoelectric device, etc. which may emit near-infrared rays and may be provided in the display apparatus 1 as an exterior member. However, the near-infrared emission portion provided in the display apparatus 1 is not limited thereto. For example, in an embodiment, the near-infrared emission portion may be provided as an interior member of the display apparatus 1.

Each light-emitting device may include a pixel electrode, an opposite electrode, and an intermediate layer disposed therebetween, and each light-receiving device may include a sensing electrode, a sensing opposite electrode, and an intermediate layer disposed therebetween. Accordingly, the first light-emitting device ED1 may include a first pixel electrode 210-1, the second light-emitting device ED2 may include a second pixel electrode 210-2, and the third light-emitting device ED3 may include a third pixel electrode 210-3. The first light-receiving device PD1 may include a first sensing electrode 210-4, the second light-receiving device PD2 may include a second sensing electrode 210-5, the third light-receiving device PD3 may include a third sensing electrode 210-6, and the fourth light-receiving device PD4 may include a fourth sensing electrode 210-7. The first to third pixel electrodes 210-1 to 210-3 and the first to fourth sensing electrodes 210-4 to 210-7 may be disposed on the substrate 100 (see FIG. 5) and spaced apart from each other. In this specification, the expression “a plan view” denotes a plane viewed in a direction perpendicular to the substrate 100. That is, the description “A and B spaced apart from each other in a plan view” denotes “A and B spaced apart from each other when viewed in a direction perpendicular to the substrate 100.”

The bank layer 209 may be disposed above the first to third pixel electrodes 210-1 to 210-3 and the first to fourth sensing electrodes 210-4 to 210-7, and may cover edges of each of the first to third pixel electrodes 210-1 to 210-3 and the first to fourth sensing electrodes 210-4 to 210-7. That is, the bank layer 209 may have a first lower opening LOP1 exposing a central portion of the first pixel electrode 210-1, a second lower opening LOP2 exposing a central portion of the second pixel electrode 210-2, and a third lower opening LOP3 exposing a central portion of the third pixel electrode 210-3. Likewise, the bank layer 209 may have a fourth lower opening LOP4 exposing a central portion of the first sensing electrode 210-4, a fifth lower opening LOP5 exposing a central portion of the second sensing electrode 210-5, a sixth lower opening LOP6 exposing a central portion of the third sensing electrode 210-6, and a seventh lower opening LOP7 exposing a central portion of the fourth sensing electrode 210-7.

In an embodiment, emission layers that emit light may be disposed in the first to third lower openings LOP1 to LOP3 of the bank layer 209, and active layers that detect the light may be disposed in the fourth to seventh lower openings LOP4 to LOP7 of the bank layer 209. The opposite electrode may be disposed on the emission layers and the active layers. A structure in which the pixel electrode, the emission layer, and the opposite electrode as described above are stacked may form a light-emitting device. A structure in which the sensing electrode, the active layer, and the opposite electrode as described above are stacked may form a light-receiving device. One opening of the bank layer 209 may correspond to one light-emitting device and may define one emission area. Alternatively, one opening of the bank layer 209 may correspond to one light-receiving device and may define one sensing area.

For example, an emission layer that emits red light may be disposed in the first lower opening LOP1, and the first lower opening LOP1 may define a first emission area EA1. Similarly, an emission layer that emits green light may be disposed in the second lower opening LOP2, and the second lower opening LOP2 may define a second emission area EA2. An emission layer that emits blue light may be disposed in the third lower opening LOP3, and the third lower opening LOP3 may define a third emission area EA3. An active layer that detects light may be disposed in the fourth lower opening LOP4, and the fourth lower opening LOP4 may define a first sensing area SA1. Similarly, an active layer that detects light may be disposed in each of the fifth to seventh lower openings LOP5 to LOP7, and the fifth to seventh lower openings LOP5 to LOP7 may define second to fourth sensing areas SA2 to SA4, respectively.

Accordingly, an area of the first lower opening LOP1 may be the same as an area of the first emission area EA1, an area of the second lower opening LOP2 may be the same as an area of the second emission area EA2, an area of the third lower opening LOP3 may be the same as an area of the third emission area EA3, and an area of the fourth lower opening LOP4 may be the same as an area of the first sensing area SA1. Likewise, areas of the fifth to seventh lower openings LOP5 to LOP7 may be the same as areas of the second to fourth sensing areas SA2 to SA4, respectively.

Each of the first to seventh lower openings LOP1 to LOP7 may have a polygonal shape when viewed in a direction (a z-axis direction) perpendicular to the substrate 100 (FIG. 5.). In other words, each of the first to third emission areas EA1 to EA3 and the first to fourth sensing areas SA1 to SA4 may have a polygonal shape when viewed in the direction (the z-axis direction) perpendicular to the substrate 100. FIG. 4 illustrates that each of the first to third emission areas EA1 to EA3 and the first to fourth sensing areas SA1 to SA4 may have a quadrangular shape when viewed in the direction (the z-axis direction) perpendicular to the substrate 100, for example, a quadrangular shape having a round edge. However, the disclosure is not limited thereto. For example, each of the first to third emission areas EA1 to EA3 and the first to fourth sensing areas SA1 to SA4 may have a circular shape or an oval shape when viewed in the direction (the z-axis direction) perpendicular to the substrate 100 according to embodiments.

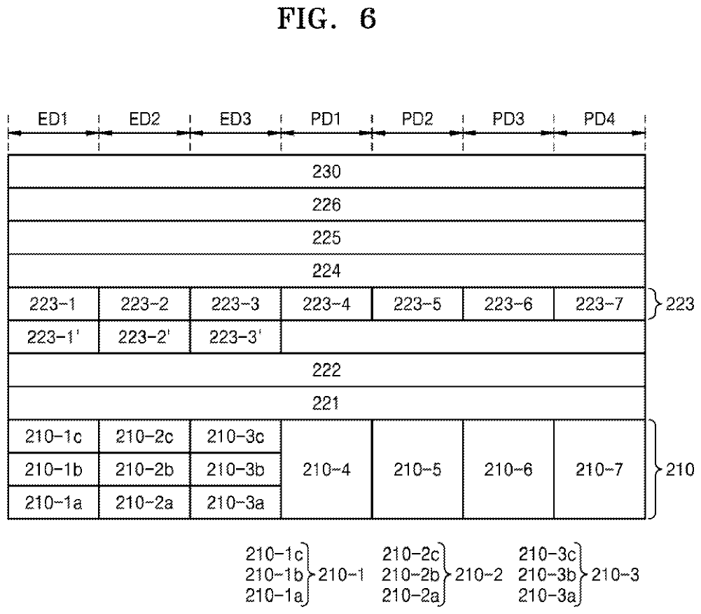

FIG. 5 is a schematic cross-sectional view of a portion of the display apparatus 1 according to an embodiment. FIG. 6 is a schematic conceptual view of a portion of the display apparatus 1 according to an embodiment. FIG. 6 is a schematic cross-sectional view of a stacked structure of light-emitting devices and light-receiving devices of the display apparatus 1 according to an embodiment.

Referring to FIG. 5, the display apparatus 1 may include the substrate 100, the thin-film transistor TFT, first to third light-emitting devices ED1 to ED3, first to fourth light-receiving devices PD1 to PD4, an encapsulation layer 300, an input sensing layer 400, a reflection prevention layer 500, and the cover window CW.

The substrate 100 may include various materials having flexible or bendable properties. For example, the substrate 100 may include glass, metal, or polymer resins. For example, the substrate 100 may include polymer resins, such as polyethersulphone, polyacrylate, polyetherimide, polyethylene naphthalate, polyethylene terephthalate, polyphenylene sulfide, polyarylate, polyimide, polycarbonate, or cellulose acetate propionate. However, various modifications may be possible. For example, the substrate 100 may have a multi-layered structure including two layers each including the polymer resins described above, and a barrier layer disposed between the two layers, the barrier layer including an inorganic material (such as, for example, silicon oxide (SiOₓ), silicon nitride (SiNₓ), silicon oxynitride (SiON), or the like).

A buffer layer 201 may be disposed on the substrate 100. The buffer layer 201 may reduce or prevent the penetration of impurities, moisture, or external substances from below the substrate 100. The buffer layer 201 may include an inorganic material such as, for example, SiOₓ, SiON, and SiNₓ, and may include a single layer or layers including the inorganic material described above.

The thin-film transistor TFT may be disposed on the buffer layer 201. The thin-film transistor TFT may include a semiconductor layer Act, a gate electrode GE, a source electrode SE, and a drain electrode DE. FIG. 5 illustrates a top-gate type in which the gate electrode GE is disposed on the semiconductor layer Act with a gate insulating layer 203 disposed therebetween. However, the disclosure is not limited thereto. For example, the thin-film transistor TFT may be a bottom-gate type.

The semiconductor layer Act may be disposed on the buffer layer 201. The semiconductor layer Act may include a channel area and a source area and a drain area disposed at both sides of the channel area. The source area and the drain area may be doped with impurities including N-type impurities or P-type impurities. The semiconductor layer Act may include amorphous silicon or polysilicon. According to an embodiment, the semiconductor layer Act may include an oxide of at least one of, for example, In, Ga, Sn, Zr, V, Hf, Cd, Ge, Cr, Ti, Al, Cs, Ce, and Zn. The semiconductor layer Act may include Zn oxide-based materials such as, for example, Zn oxide, In—Zn oxide, Ga—In—Zn oxide, etc. The semiconductor layer Act may include a semiconductor including a metal such as, for example, In, Ga, or Sn. For example, the semiconductor layer Act may include In—Ga—Zn—O (IGZO), In—Sn—Zn—O (ITZO), or In—Ga—Sn—Zn—O (IGTZO).

The gate electrode GE may be disposed on the semiconductor layer Act to at least partially overlap the semiconductor layer Act. In an embodiment, the gate electrode GE may overlap the channel area of the semiconductor layer Act. The gate electrode GE may include various conductive materials including, for example, Mo, Al, Cu, Ti, etc., and may include various layered structures. For example, the gate electrode GE may include a Mo layer and an Al layer or may have a layered structure including Mo/Al/Mo layers.

A gate insulating layer 203 disposed between the semiconductor layer Act and the gate electrode GE may include an inorganic insulating material such as, for example, SiOₓ, SiNₓ, SiON, aluminum oxide, titanium oxide, tantalum oxide, and hafnium oxide. The gate insulating layer 203 may include a single layer or layers including the materials described above.

The source electrode SE and the drain electrode DE may be in contact with the source area and the drain area of the semiconductor layer Act through a contact hole. The source electrode SE and the drain electrode DE may include various conductive materials including, for example, Mo, Al, Cu, Ti, etc., and may have various layered structures. For example, the source electrode SE and the drain electrode DE may include a Ti layer and an Al layer or may have a layered structure including Ti/Al/Ti layers.

An interlayer insulating layer 205 may include an inorganic insulating material such as, for example, SiOₓ, SiNₓ, SiON, aluminum oxide, titanium oxide, tantalum oxide, hafnium oxide, etc. The interlayer insulating layer 205 may include a single layer or layers including the material described above. The gate insulating layer 203 and the interlayer insulating layer 205 including the inorganic material as described above may be formed by, for example, chemical vapor deposition (CVD), atomic layer deposition (ALD), or the like. However, the disclosure is not limited thereto.

The thin-film transistor TFT may be covered by an organic insulating layer 207. For example, the organic insulating layer 207 may cover the source electrode SE and the drain electrode DE. The organic insulating layer 207 may be a planarized insulating layer and may include a substantially flat upper surface. The organic insulating layer 207 may include an organic insulating material such as, for example, a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. According to an embodiment, the organic insulating layer 207 may include polyimide.

The first to third light-emitting devices ED1 to ED3 and the first to fourth light-receiving devices PD1 to PD4 may be disposed on the organic insulating layer 207 and spaced apart from each other. Each of the first to third light-emitting devices ED1 to ED3 may emit light of a different color from each other. For example, the first light-emitting device ED1 may emit red light, the second light-emitting device ED2 may emit green light, and the third light-emitting device ED3 may emit blue light. The first to fourth light-receiving devices PD1 to PD4 may detect light emitted by the first to third light-emitting devices ED1 to ED3 or a near-infrared emission portion and reflected by an object.

The first light-emitting device ED1 may include the first pixel electrode 210-1, a first emission layer 223-1, and the opposite electrode 230. The second light-emitting device ED2 may include the second pixel electrode 210-2, a second emission layer 223-2, and the opposite electrode 230. The third light-emitting device ED3 may include the third pixel electrode 210-3, a third emission layer 223-3, and the opposite electrode 230. The first light-receiving device PD1 may include the first sensing electrode 210-4, a first active layer 223-4, and the opposite electrode 230. The second light-receiving device PD2 may include the second sensing electrode 210-5, a second active layer 223-5, and the opposite electrode 230. The third light-receiving device PD3 may include the third sensing electrode 210-6, a third active layer 223-6, and the opposite electrode 230. The fourth light-receiving device PD4 may include the fourth sensing electrode 210-7, a fourth active layer 223-7, and the opposite electrode 230.

That is, the first to third pixel electrodes 210-1 to 210-3 included in the first to third light-emitting devices ED1 to ED3, respectively, and the first to fourth sensing electrodes 210-4 to 210-7 included in the first to fourth light-receiving devices PD1 to PD4, respectively, may be patterned for respective pixels. The opposite electrode 230 of the first to third light-emitting devices ED1 to ED3 and the first to fourth light-receiving devices PD1 to PD4 may be integrally provided throughout the first to third light-emitting devices ED1 to ED3 and the first to fourth light-receiving devices PD1 to PD4. The first to third emission layers 223-1 to 223-3 may be disposed between the first to third pixel electrodes 210-1 to 210-3 and the opposite electrode 230, and the first to fourth active layers 223-4 to 223-7 may be disposed between the first to fourth sensing electrodes 210-4 to 210-7 and the opposite electrode 230.

The first to third pixel electrodes 210-1 to 210-3 and the first to fourth sensing electrodes 210-4 to 210-7 may be disposed on the substrate 100 and spaced apart from each other. In this case, in an embodiment, the first to third pixel electrodes 210-1 to 210-3 may have different stacked structures from the first to fourth sensing electrodes 210-4 to 210-7.

In an embodiment, the first to third pixel electrodes 210-1 to 210-3 may include transflective electrodes, and the first to fourth sensing electrodes 210-4 to 210-7 may include transparent electrodes. Referring to FIG. 6, the first to third pixel electrodes 210-1 to 210-3 may include transflective metal layers 210-1b, 210-2b, and 210-3b and transparent conductive layers 210-1a, 210-1c, 210-2a, 210-2c, 210-3a, and 210-3c. For example, the first to third pixel electrodes 210-1 to 210-3 may include the transflective metal layers 210-1b, 210-2b, and 210-3b, the transparent conductive layers 210-1a, 210-2a, and 210-3a disposed below the transflective metal layers 210-1b, 210-2b, and 210-3b, and the transparent conductive layers 210-1c, 210-2c, and 210-3c disposed above the transflective metal layers 210-1b, 210-2b, and 210-3b.

The transparent conductive layers 210-1a, 210-1c, 210-2a, 210-2c, 210-3a, and 210-3c may include transparent conductive oxide (TCO). For example, the transparent conductive layers 210-1a, 210-1c, 210-2a, 210-2c, 210-3a, and 210-3c may include at least one of, for example, indium tin oxide (ITO), indium zinc oxide (IZO), zinc oxide (ZnO), indium oxide (In₂O₃), indium gallium oxide (IGO), and aluminum zinc oxide (AZO). The transflective metal layers 210-1b, 210-2b, and 210-3b may include at least one of, for example, Ag, Al, Mg, Li, Ca, Cu, LiF/Ca, LiF/Al, MgAg, and CaAg. According to an embodiment, each of the first to third pixel electrodes 210-1 to 210-3 may include triple layers of ITO/Ag/ITO, and the Ag layer may be formed as a thin film having a thickness of dozens to hundreds of angstrom (A) to have transflective properties.

On the contrary, the first to fourth sensing electrodes 210-4 to 210-7 may include transparent electrodes including transparent conductive layers. That is, the first to fourth sensing electrodes 210-4 to 210-7 may include TCO. For example, the first to fourth sensing electrodes 210-4 to 210-7 may include at least one of, for example, ITO, IZO, ZnO, In₂O₃, IGO, and AZO. According to an embodiment, the first to fourth sensing electrodes 210-4 to 210-7 may include a transparent conductive layer such as ITO and may have a transmittance that is equal to or greater than about 90%.

Each of the first to fourth sensing electrodes 210-4 to 210-7 may have the same thickness as each other. Here, each of the first to fourth sensing electrodes 210-4 to 210-7 may be a transparent conductive layer including ITO having a thickness of about 10 Å to about 1000 Å. According to an embodiment, the first sensing electrode 210-4 may have a structure in which the transparent conductive layers 210-1a and 210-1c of the first pixel electrode 210-1 are stacked. In other words, the first sensing electrode 210-4 may have the stacked structure of the first pixel electrode 210-1, from which the transflective metal layer 210-1b is excluded.

Each of the first to third pixel electrodes 210-1 to 210-3 and the first to fourth sensing electrodes 210-4 to 210-7 may be in contact with any one of the source electrode SE and the drain electrode DE, and may be electrically connected to the thin-film transistor TFT as illustrated in FIG. 5. In an embodiment, each of the first to third pixel electrodes 210-1 to 210-3 and the first to fourth sensing electrodes 210-4 to 210-7 may be in contact with any one of the source electrode SE and the drain electrode DE through a contact hole formed in the organic insulating layer 207.

The bank layer 209 may be disposed above the organic insulating layer 207. The bank layer 209 may define the emission area EA and the sensing area SA by having openings corresponding to the light-emitting device ED and the light-receiving device PD. In an embodiment, the bank layer 209 may have the first to seventh lower openings LOP1 to LOP7. The first to third lower openings LOP1 to LOP3 may expose central portions of the first to third pixel electrodes 210-1 to 210-3, respectively, and the fourth to seventh lower openings LOP4 to LOP7 may expose central portions of the first to fourth sensing electrodes 210-4 to 210-7, respectively.

As illustrated in FIG. 5, the bank layer 209 may increase distances between edges of the first to third pixel electrodes 210-1 to 210-3 and the opposite electrode 230 above the first to third pixel electrodes 210-1 to 210-3. Similarly, the bank layer 209 may increase distances between edges of the first to fourth sensing electrodes 210-4 to 210-7 and the opposite electrode 230 above the first to fourth sensing electrodes 210-4 to 210-7. Thus, the occurrence of arc, etc. at the edges of the first to third pixel electrodes 210-1 to 210-3 or the edges of the first to fourth sensing electrodes 210-4 to 210-7 may be prevented. The bank layer 209 may include an organic material such as, for example, polyimide or hexamethyldisiloxane (HMDSO).

The opposite electrode 230 may be disposed on the first pixel electrode 210-1. The opposite electrode 230 may be integrally provided throughout the first to third light-emitting devices ED1 to ED3 and the first to fourth light-receiving devices PD1 to PD4. Thus, the opposite electrode 230 may be disposed on the second pixel electrode 210-2 and the third pixel electrode 210-3 and also on the first to fourth sensing electrodes 210-4 to 210-7. According to an embodiment, the opposite electrode 230 may include a reflection electrode. For example, the opposite electrode 230 may include at least one of Ag, Al, Mg, Li, Ca, Cu, LiF/Ca, LiF/Al, MgAg, and CaAg having a certain thickness to have an increased reflectivity.

An intermediate layer may be disposed between each of the first to third pixel electrodes 210-1 to 210-3 and the opposite electrode 230. Likewise, an intermediate layer may also be disposed between each of the first to fourth sensing electrodes 210-4 to 210-7 and the opposite electrode 230. The intermediate layers disposed on the pixel electrodes may include a first common layer 221, a second common layer 222, the first to third emission layers 223-1 to 223-3, a buffer layer 224, a third common layer 225, and a fourth common layer 226. The intermediate layers disposed on the sensing electrodes may include the first common layer 221, the second common layer 222, the active layers 223-4 to 223-7, the buffer layer 224, the third common layer 225, and the fourth common layer 226. The first to third emission layers 223-1 to 223-3 may be patterned for the first to third light-emitting devices ED1 to ED3, respectively, and the active layers 223-4 to 223-7 may be patterned for the first to fourth light-receiving devices PD1 to PD4, respectively.

According to an embodiment, the first light-emitting device ED1 may emit red light, the second light-emitting device ED2 may emit green light, and the third light-emitting device ED3 may emit blue light. To realize the emission of light described above, the first emission layer 223-1 may emit red light, the second emission layer 223-2 may emit green light, and the third emission layer 223-3 may emit blue light. The first to fourth light-receiving devices PD1 to PD4 may detect light emitted by the first to third light-emitting devices ED1 to ED3 and a near-infrared emission portion and reflected by an object. To realize the detection of light described above, the first to fourth active layers 223-4 to 223-7 may detect light in an increased wavelength range, and thus, may absorb light of a visible band and light of a near-infrared band. This may be due to a non-cavity structure of the light-receiving device PD, which is to be described below.

The first to third emission layers 223-1 to 223-3 may include an organic material including a fluorescent or phosphorous material emitting red, green, blue, or white light. The first to third emission layers 223-1 to 223-3 may include organic emission layers including a low molecular-weight organic material or a high molecular-weight organic material. For example, the first to third emission layers 223-1 to 223-3 may be organic emission layers and may include, for example, copper phthalocyanine, tris-8-hydroxyquinoline aluminum, a poly-phenylenevinylene (PPV)-based material, or a polyfluorene-based material.

According to an embodiment, the first to third emission layers 223-1 to 223-3 may include a host material and a dopant material. The dopant material may emit a predetermined color and may include an emission material. The emission material may include at least one of, for example, a phosphorescent dopant, a fluorescent dopant, and quantum dots. The host material is a main material of the first to third emission layers 223-1 to 223-3 and helps the dopant material emit light.

The first to fourth active layers 223-4 to 223-7 may generate an exciton by receiving light from the outside and may separate the generated exciton into a hole and an electron. When a positive (+) potential is applied to the first to fourth sensing electrodes 210-4 to 210-7, and a negative (−) potential is applied to the opposite electrode 230, the hole separated in the first to fourth active layers 223-4 to 223-7 may move toward the opposite electrode 230, and the electron separated in the first to fourth active layers 223-4 to 223-7 may move toward the first to fourth sensing electrodes 210-4 to 210-7. Thus, a light current may be formed in a direction from the first to fourth sensing electrodes 210-4 to 210-7 toward the opposite electrode 230. When a bias is applied between the first to fourth sensing electrodes 210-4 to 210-7 and the opposite electrode 230, a dark current may flow in the light-receiving device PD. When light is incident into the light-receiving device PD, a light current may flow in the light-receiving device PD. According to an embodiment, the light-receiving device PD may detect the amount of light based on a ratio between a light current and a dark current.

The first to fourth active layers 223-4 to 223-7 may include a p-type organic semiconductor and an n-type organic semiconductor. The p-type organic semiconductor may function as an electron donor, and the n-type organic semiconductor may function as an electron acceptor. According to an embodiment, the first to fourth active layers 223-4 to 223-7 may be mixed layers in which the p-type organic semiconductor and the n-type organic semiconductor are mixed. In this case, the first to fourth active layers 223-4 to 223-7 may be formed by co-deposition of the p-type organic semiconductor and the n-type organic semiconductor. When the first to fourth active layers 223-4 to 223-7 are mixed layers, an exciton may be generated within a diffusion length from a donor-acceptor interface.

The p-type organic semiconductor may be a compound functioning as an electron donor supplying electrons. According to an embodiment, the p-type organic semiconductor may include, for example, a α,α-bis(2,2-dicyanovinyl)-quinquethiophene (DCV5T)-based material, and when the first to fourth active layers 223-4 to 223-7 include the DCV5T-based material, the first to fourth active layers 223-4 to 223-7 may absorb light in an increased wavelength band. However, the p-type organic semiconductor is not limited thereto. For example, in an embodiment, the p-type organic semiconductor may be an electron-donating organic compound. For example, the p-type organic semiconductor may include a metal complex, etc. having as ligand a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a merocyanine compound, an oxonol compound, a polyamine compound, an indole compound, a pyrole compound, a pyrazole compound, a polyarylene compound, a condensed aromatic carbocyclic ring (naphthalene derivatives, anthracene derivatives, phenanthrene derivatives, tetracene derivatives, pyrene derivatives, perylene derivatives, and fluoranthene derivatives), and a nitrogen-containing heterocylic ring, but is not limited thereto.

According to an embodiment, the n-type organic semiconductor may be a compound functioning as an electron acceptor accepting electrons. In an embodiment, the n-type organic semiconductor may be an electron-accepting organic compound. For example, the n-type organic semiconductor may include a metal complex, etc. having as ligand fullerene, fullerene derivatives, a condensed aromatic carbocyclic ring (naphthalene derivatives, anthracene derivatives, phenanthrene derivatives, tetracene derivatives, pyrene derivatives, perylene derivatives, and fluoranthene derivatives), a 5- to 7-membered heterocyclic compound containing a nitrogen atom, an oxygen atom, and a sulfur atom (for example, pyridine, pyrazine, pyrimidine, pyridazine, triazine, quinoline, quinoxaline, quinazoline, phthalazine, cinnolin, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolo-pyridin, thiadiazole pyridine, dibenzazepine, tribenzazepine, etc.), a polyarylene compound, a fluorene compound, a cyclopentadiene compound, a sylil compound, and a nitrogen-containing heterocyclic compound, but is not limited thereto.

The light-emitting device ED may further include optical auxiliary layers 223-1′, 223-2′, and 223-3′ that adjust an optical distance for micro-cavity of the light-emitting device ED. The optical auxiliary layers 223-1′ to 223-3′ may be disposed between a hole transport region to be described below and the first to third emission layers 223-1 to 223-3. For example, the optical auxiliary layers 223-1′ to 223-3′ may be disposed between the second common layer 222 and the first to third emission layers 223-1 to 223-3. The optical auxiliary layers 223-1′ to 223-3′ may be patterned for the light-emitting devices ED, respectively. The optical auxiliary layers 223-1′ to 223-3′ may have a thickness proportional to an emission wavelength of the light-emitting device ED. According to an embodiment, the optical auxiliary layer 223-1′ of the first light-emitting device ED1 that emits red light of a wavelength of about 600 nm to about 650 nm may have a thickness of about 650 Å to about 900 Å, and the optical auxiliary layer 223-2′ of the second light-emitting device ED2 that emits green light of a wavelength of about 500 nm to about 550 nm may have a thickness of about 250 Å to about 500 Å. The optical auxiliary layers 223-1′ to 223-3′ may be disposed between the hole transport region and the first to third emission layers 223-1 to 223-3, and thus, may include a material of a hole transport layer (HTL). For example, the optical auxiliary layers 223-1′ to 223-3′ may include the same material as the second common layer 222 to be described below.

The light-emitting device ED and the light-receiving device PD may further include a charge auxiliary layer that facilitates movement of holes and electrons. The charge auxiliary layer may include the first common layer 221, the second common layer 222, the buffer layer 224, the third common layer 225, and the fourth common layer 226. The first common layer 221 and the second common layer 222 may be disposed between the first to third pixel electrodes 210-1 to 210-3 and the first to third emission layers 223-1 to 223-3, and between the first to fourth sensing electrodes 210-4 to 210-7 and the first to fourth active layers 223-4 to 223-7. The buffer layer 224, the third common layer 225, and the fourth common layer 226 may be disposed between the first to third emission layers 223-1 to 223-3 and the opposite electrode 230, and between the first to fourth active layers 223-4 to 223-7 and the opposite electrode 230. That is, the first to fourth common layers 221 to 226 and the buffer layer 224 may be integrally provided throughout the light-emitting devices ED and the light-receiving devices PD.

According to an embodiment, the hole transport region may be defined between the first to third pixel electrodes 210-1 to 210-3 and the first to third emission layers 223-1 to 223-3, and between the first to fourth sensing electrodes 210-4 to 210-7 and the first to fourth active layers 223-4 to 223-7. Also, an electron transport region may be defined between the first to third emission layers 223-1 to 223-3 and the opposite electrode 230, and between the first to fourth active layers 223-4 to 223-7 and the opposite electrode 230.

The hole transport region may facilitate the movement of holes, and the hole transport region may have a single-layered structure or a multi-layered structure. The hole transport region may include at least one of a hole injection layer (HIL), an HTL, and an electron blocking layer (EBL). According to an embodiment, the first common layer 221 disposed in the hole transport region may be the HIL, and the second common layer 222 disposed in the hole transport region may be the HTL.

A thickness of the hole transport region may be about 50 Å to about 10000 Å, for example, about 100 Å to about 4000 Å. When the hole transport region includes the HIL, the HTL, or a combination thereof, a thickness of the HIL may be about 100 Å to about 9000 Å, for example, about 100 Å to about 1000 Å, and a thickness of the HTL may be about 50 Å to about 2000 Å, for example, about 100 Å to about 1500 Å. When the thicknesses of the HIL and the HTL satisfy the ranges described above, the hole transport characteristics that suffice may be obtained without a substantial rise of a driving voltage.

The first common layer 221 and the second common layer 222 may include at least one of, for example, m-MTDATA, TDATA, 2-TNATA, NPB(NPD), β-NPB, TPD, Spiro-TPD, Spiro-NPB, methylated-NPB, TAPC, HMTPD, 4,4′,4-tris(N-carbazolyl) triphenylamine (TCTA), polyaniline/dodecylbenzenesulfonic acid (pani/DBSA), polyaniline/camphor sulfonic acid (pani/CSA), poly(3,4-ethylenedioxythiophene)/poly(4-styrenesulfonate) (PEDOT/PSS), polyaniline/poly(4-styrenesulfonate) (PANI/PSS).

The electron transport region may facilitate the movement of electrons and may have a single-layered structure or a multi-layered structure. The electron transport region may include at least one layer from among, for example, an electron injection layer (EIL), an electron transport layer (ETL), and a hole blocking layer (HBL). According to an embodiment, the third common layer 225 disposed in the electron transport region may be the ETL, and the fourth common layer 226 disposed in the electron transport region may be the EIL.

A thickness of the electron transport region may be about 100 Å to about 5000 Å, for example, about 160 Å to about 4000 Å. When the electron transport region includes a buffer layer, an HBL, an electron adjusting layer, an ETL, or a combination thereof, a thickness of the buffer layer, the HBL, or the electron adjusting layer may be different from each other. For example, the thickness of the buffer layer, the HBL, or the electron adjusting layer may be about 20 Å to about 1000 Å, for example, about 30 Å to about 300 Å, and the thickness of the ETL may be about 100 Å to about 1000 Å, for example, about 150 Å to about 500 Å. When the thickness(es) of the buffer layer, the HBL, the electron adjusting layer, the ETL, and/or the electron transport region satisfies (satisfy) the ranges described above, the electron transport characteristics that suffice may be obtained without a substantial rise of a driving voltage.

The buffer layer 224 may include an inorganic material such as, for example, SiOₓ, SiNₓ, and/or SiON, and the third common layer 225 and the fourth common layer 226 may include at least one compound including, for example, 2,9-Dimethyl-4,7-diphenyl-1,10-phenanthroline (BCP), 4,7-Diphenyl-1,10-phenanthroline (Bphen), Alq3, BAlq, 3-(Biphenyl-4-yl)-5-(4-tert-butylphenyl)-4-phenyl-4H-1,2,4-triazole (TAZ), and NTAZ.

As the structure of the light-emitting device ED described above, a cavity structure may be formed in the first to third emission areas EA1 to EA3. That is, the cavity structure may be formed between the first pixel electrode 210-1 formed as a transflective electrode and the opposite electrode 230 formed as a reflection electrode. Likewise, the second pixel electrode 210-2 and the third pixel electrode 210-3 may also include the transflective metal layers 210-2b and 210-3b, and thus, cavity structures may be formed between the second pixel electrode 210-2 and the opposite electrode 230 and between the third pixel electrode 210-3 and the opposite electrode 230.

In an embodiment, a distance between the first pixel electrode 210-1 and the opposite electrode 230 may be configured to satisfy a constructive interference condition, and light emitted from the first emission layer 223-1 may have a reduced full width at half maximum and an increased intensity by being repetitively reflected from the first pixel electrode 210-1 and the opposite electrode 230. Due to this microcavity structure, the light extraction efficiency of the first light-emitting device ED1 may be increased. The cavity structure described above may be likewise applied to the second light-emitting device ED2 and the third light-emitting device ED3.

On the contrary, as the structure of the light-receiving device PD described above, a non-cavity structure may be formed in the first to fourth sensing areas SA1 to SA4. That is, a non-cavity structure may be formed between the first sensing electrode 210-4 formed as a transparent electrode and the opposite electrode 230 formed as a reflection electrode. Likewise, the second to fourth sensing electrodes 210-5 to 210-7 may include only transparent conductive layers, and thus, non-cavity structures may be formed between the second sensing electrode 210-5 and the opposite electrode 230, between the third sensing electrode 210-6 and the opposite electrode 230, and between the fourth sensing electrode 210-7 and the opposite electrode 230.

In an embodiment, the first sensing electrode 210-4 may be formed as a transparent electrode, and thus, light that is incident into the first light-receiving device PD1 may not reciprocate between the first sensing electrode 210-4 and the opposite electrode 230. Rather, the light that is incident into the first light-receiving device PD1 may be emitted to the outside by being directly transmitted through the first sensing electrode 210-4 or may be emitted to the outside by being transmitted through the first sensing electrode 210-4 after being reflected by the opposite electrode 230. The non-cavity structure described above may be likewise applied to the second to fourth light-receiving devices PD2 to PD4.

The cavity structure of the first to third light-emitting devices ED1 to ED3 may cause the occurrence of constructive interference by having light reciprocate between two electrodes, and thus, the light extraction efficiency of each light-emitting device ED may be increased. However, when this cavity structure is applied to the light-receiving device PD, the external quantum efficiency (EQE) may be increased, but the straight feature of light may be increased, so that the light-receiving device PD may absorb only light of a single color. When the light-receiving device PD absorbs only light of a single color, a sensor degree and the sensor reliability may be decreased, compared to a case where the light-receiving device PD absorbs light in an increased wavelength band.

Accordingly, according to the display apparatus 1 according to an embodiment, the non-cavity structure may be applied to the sensing area SA, and thus, the light-receiving device PD may not absorb only light of a single color, but may absorb light in an increased wavelength band. In an embodiment, when the non-cavity structure is applied to the light-receiving device PD, the light-receiving device PD may absorb not only light of a visible band emitted from the first to third light-emitting devices ED1 to ED3, but may also absorb light of a near-infrared band emitted from a near-infrared emission portion. When the light-receiving device PD absorbs light in an increased wavelength band, the light-receiving device PD may detect light in an increased range, and thus, the light detection performance of the light-receiving device PD may be increased.

For example, light of the near-infrared band may have an increased wavelength and may have a greater transmittance than light of the visible band, and thus, an object may be accurately recognized. Therefore, the first to third light-receiving devices PD1 to PD3 that absorb light of the visible band may be used as a fingerprint sensor, and the fourth light-receiving device PD4 that absorbs light of the near-infrared band may be used as a touch sensor. In the case of a display apparatus including the fourth light-receiving device PD4, a touch sensor layer, etc., which are typically additionally disposed, may be omitted.

As a result, the display apparatus 1 according to an embodiment may have the increased light extraction efficiency by implementing a cavity structure in the entire emission area EA, and may also have increased sensing degree and sensing reliability in the sensing area SA.

Referring to FIG. 5 again, a capping layer 240 may be disposed above the light-emitting device ED and the light-receiving device PD. For example, the capping layer 240 may be disposed on the opposite electrode 230. The capping layer 240 may facilitate the movement of holes by reducing an energy barrier of the holes moving toward the HTL and an anode. The capping layer 240 may include, for example, a fluorene-based compound, a carbazole-based compound, a diarylamine-based compound, a triarylamine-based compound, a dibenzofuran-based compound, a dibenzothiophene-based compound, a dibenzosilole-based compound, or a combination thereof.

The encapsulation layer 300 may be disposed above the light-emitting device ED and the light-receiving device PD, and may planarize upper surfaces of the light-emitting device ED and the light-receiving device PD and prevent the penetration of pollutants. For example, the encapsulation layer 300 may be disposed on the capping layer 240. The encapsulation layer 300 may include at least one inorganic encapsulation layer and at least one organic encapsulation layer. According to an embodiment, FIG. 5 illustrates that the encapsulation layer 300 may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among, for example, aluminum oxide, titanium oxide, tantalum oxide, hafnium oxide, ZnO, SiOₓ, SiNₓ, and SiON. The organic encapsulation layer 320 may include a polymer-based material. The polymer-based material may include, for example, acryl-based resins, epoxy-based resins, polyimide, polyethylene, etc. According to an embodiment, the organic encapsulation layer 320 may include acrylate. The organic encapsulation layer 320 may be formed by curing a monomer or coating a polymer. The organic encapsulation layer 320 may be transparent.

The input sensing layer 400 may be disposed on the encapsulation layer 300. The input sensing layer 400 may obtain coordinate information based on an external input, for example, a touch event. The input sensing layer 400 may include a plurality of touch electrodes and a touch insulating layer.

The reflection prevention layer 500 may be disposed above the input sensing layer 400. The reflection prevention layer 500 may include a light blocking layer BM and a color filter CF. The light blocking layer BM may be disposed on the input sensing layer 400. The light blocking layer BM may at least partially absorb external light or internal reflection light. The light blocking layer BM may include black pigments. The light blocking layer BM may include a black matrix. The light blocking layer BM may include a first upper opening UOP1 disposed above the first light-emitting device ED1, a second upper opening UOP2 disposed above the second light-emitting device ED2, and a third upper opening UOP3 disposed above the third light-emitting device ED3. Likewise, the light blocking layer BM may include a fourth upper opening UOP4 disposed above the first light-receiving device PD1, a fifth upper opening UOP4 disposed above the second light-receiving device PD2, a sixth upper opening UOP6 disposed above the third light-receiving device PD3, and a seventh upper opening UOP7 disposed above the fourth light-receiving device PD4. That is, the first to third upper openings UOP1 to UOP3 may overlap the first to third emission areas EA1 to EA3, respectively, and the first to fourth upper openings UOP4 to UOP7 may overlap the first to fourth sensing areas SA1 to SA4, respectively. Areas of the first to third upper openings UOP1 to UOP3 may respectively be the same as or greater than areas of the first to third lower openings LOP1 to LOP3 disposed in the bank layer 209. Also, areas of the fourth to seventh upper openings UOP4 to UOP7 may respectively be the same as or greater than areas of the fourth to seventh lower openings LOP4 to LOP7 disposed in the bank layer 209.

The color filter CF may be disposed on the light blocking layer BM. The color filter CF may transmit only light having a wavelength within a predetermined band. The color filter CF may include first to third color filters CF1 to CF3 and first to fourth light-receiving filters CF4 to CF7. The first color filter CF1 may fill the first upper opening UOP1 and overlap the first emission area EA1, the second color filter CF2 may fill the second upper opening UOP2 and overlap the second emission area EA2, and the third color filter CF3 may fill the third upper opening UOP3 and overlap the third emission area EA3. Likewise, the first light-receiving color filter CF4 may fill the fourth upper opening UOP4 and overlap the first sensing area SA1, the second light-receiving color filter CF5 may fill the fifth upper opening UOP5 and overlap the second sensing area SA2, the third light-receiving color filter CF6 may fill the sixth upper opening UOP6 and overlap the third sensing area SA3, and the fourth light-receiving color filter CF7 may fill the seventh upper opening UOP7 and overlap the fourth sensing area SA4.

The first color filter CF1 may transmit light emitted from the first light-emitting device ED1. For example, when the first light-emitting device ED1 emits red light, the first color filter CF1 may be a red color filter transmitting light of a wavelength band of about 600 nm to about 750 nm. Similarly, the second color filter CF2 may transmit light emitted from the second light-emitting device ED2. For example, when the second light-emitting device ED2 emits green light, the second color filter CF2 may be a green color filter transmitting light of a wavelength band of about 495 nm to about 600 nm. The third color filter CF3 may transmit light emitted from the third light-emitting device ED3. For example, when the third light-emitting device ED3 emits blue light, the third color filter CF3 may be a blue color filter transmitting light of a wavelength band of about 380 nm to about 495 nm.

The first light-receiving color filter CF4 may transmit light emitted from the first light-emitting device ED1 and reflected by an object. That is, the first light-receiving color filter CF4 may include the same material as the first color filter CF1 and may transmit light of the same color as the first color filter CF1. For example, the first light-receiving color filter CF4 may be a red color filter transmitting light of a wavelength band of about 600 nm to about 750 nm. Similarly, the second light-receiving color filter CF5 may transmit light emitted from the second light-emitting device ED2 and reflected by an object. That is, the second light-receiving color filter CF5 may include the same material as the second color filter CF2 and may transmit light of the same color as the second color filter CF2. For example, the second light-receiving color filter CF5 may be a green color filter transmitting light of a wavelength band of about 495 nm to about 600 nm. The third light-receiving color filter CF6 may transmit light emitted from the third light-emitting device ED3 and reflected by an object. That is, the third light-receiving color filter CF6 may include the same material as the third color filter CF3 and may transmit light of the same color as the third color filter CF3. For example, the third light-receiving color filter CF6 may be a blue color filter transmitting light of a wavelength band of about 380 nm to about 495 nm.

The fourth light-receiving color filter CF7 may transmit light emitted from a near-infrared emission portion and reflected by an object. That is, the fourth light-receiving color filter CF7 may not transmit the light of a visible band emitted from the first to third light-emitting devices ED1 to ED3, and thus, may include a different material from the first to third color filters CF1 to CF3. For example, the fourth light-receiving color filter CF7 may be a filter transmitting light of a wavelength band of about 750 nm to about 1000 nm.

As described above, each of the first to fourth active layers 223-4 to 223-7 may absorb light of the visible band and light of the near-infrared band through the non-cavity structure of the light-receiving device PD. When the color filter CF is disposed above this structure of the light-receiving device PD, each light-receiving device PD may mainly detect light which may be transmitted through the color filter CF disposed thereabove. For example, the first light-receiving color filter CF4, which is a red color filter, may be disposed above the first light-receiving device PD1, and thus, the first light-receiving device PD1 may detect light of a wavelength band of about 600 nm to about 750 nm. Likewise, the second light-receiving color filter CF5, which is a green color filter, may be disposed above the second light-receiving device PD2, and thus, the second light-receiving device PD2 may mainly detect light of a wavelength band of about 495 nm to about 600 nm. The third light-receiving color filter CF6, which is a blue color filter, may be disposed above the third light-receiving device PD3, and thus, the third light-receiving device PD3 may detect light of a wavelength band of about 380 nm to about 495 nm. The fourth light-receiving color filter CF7, which is a near-infrared filter, may be disposed above the fourth light-receiving device PD4, and thus, the fourth light-receiving device PD4 may detect light of a wavelength band of about 750 nm to about 1000 nm.

By arranging the first to fourth light-receiving color filters CF4 to CF7 above the light-receiving devices PD, each light-receiving device PD may mainly detect light of a predetermined wavelength band. Thus, in the display apparatus 1 according to an embodiment, the sensing degree of the sensing area SA may further be increased.

The cover window CW may be disposed above the reflection prevention layer 500. The cover window CW may include at least one of, for example, glass, sapphire, and plastic. The cover window CW may include, for example, ultra-thin glass (UTG) or colorless polyimide (CPI).

An adhesion member AD may be disposed between the cover window CW and the reflection prevention layer 500. Thus, the adhesion member AD may couple the cover window CW with the reflection prevention layer 500. The adhesion member AD is not limited to particular types. The adhesion member may include a pressure sensitive adhesive (PSA).

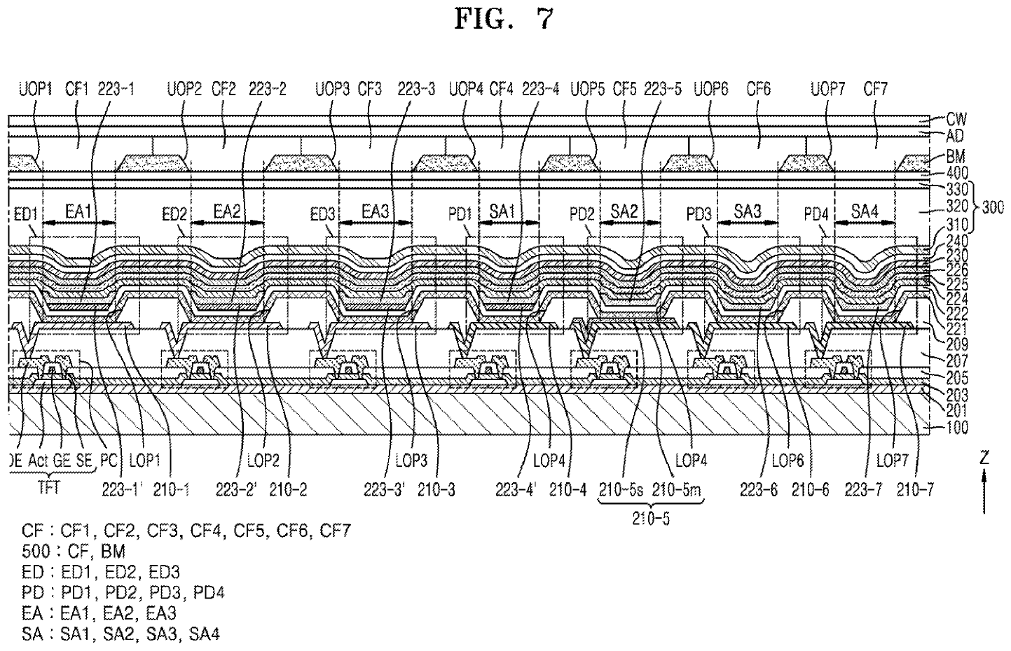

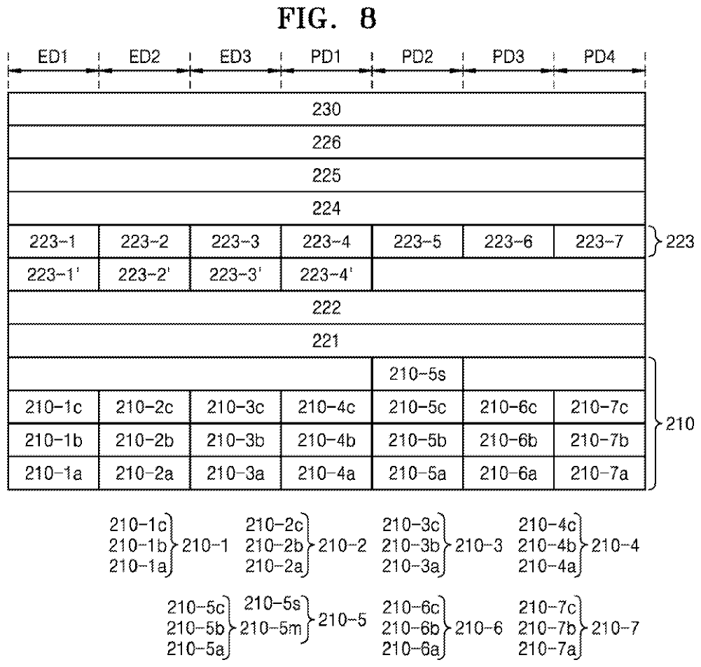

FIG. 7 is a schematic cross-sectional view of a portion of a display apparatus according to an embodiment. FIG. 8 is a schematic conceptual view of a portion of a display apparatus according to an embodiment. FIG. 8 is a schematic cross-sectional view of a stacked structure of light-emitting devices and light-receiving devices of the display apparatus according to an embodiment.

Referring to FIGS. 7 and 8, except for aspects about the light-receiving device PD, other aspects are the same as described above with reference to FIGS. 5 and 6. For the elements of FIGS. 7 and 8 indicated by the same reference numerals as the elements of FIGS. 5 and 6, the descriptions of FIGS. 5 and 6 may be referred to, and hereinafter, different aspects are mainly described.

Referring to FIGS. 7 and 8, the first light-receiving device PD1 may include the first sensing electrode 210-4, the first active layer 223-4, and the opposite electrode 230. The second light-receiving device PD2 may include the second sensing electrode 210-5, the second active layer 223-5, and the opposite electrode 230, and the third light-receiving device PD3 may include the third sensing electrode 210-6, the third active layer 223-6, and the opposite electrode 230. The fourth light-receiving device PD4 may include the fourth sensing electrode 210-7, the fourth active layer 223-7, and the opposite electrode 230.

The first to third pixel electrodes 210-1 to 210-3 and the first to fourth sensing electrodes 210-4 to 210-7 may be disposed on the substrate 100 and are spaced apart from each other. Here, at least one of the first to fourth sensing electrodes 210-4 to 210-7 may include a different stacked structure from the first to third pixel electrodes 210-1 to 210-3.

In an embodiment, the first to third pixel electrodes 210-1 to 210-3 may be transflective electrodes, and the first to fourth sensing electrodes 210-4 to 210-7 may also be transflective electrodes. However, at least one of the first to fourth sensing electrodes 210-4 to 210-7 may have a stacked structure further including a sub-sensing electrode 210-5s.

Referring to FIG. 8, the first to third pixel electrodes 210-1 to 210-3 may include transflective metal layers 210-1b, 210-2b, and 210-3b and transparent conductive layers 210-1a, 210-1c, 210-2a, 210-2c, 210-3a, and 210-3c. That is, the first to third pixel electrodes 210-1 to 210-3 may include the transflective metal layers 210-1b, 210-2b, and 210-3b, the transparent conductive layers 210-1a, 210-2a, and 210-3a disposed below the transflective metal layers 210-1b, 210-2b, and 210-3b, and the transparent conductive layers 210-1c, 210-2c, and 210-3c disposed above the transflective metal layers 210-1b, 210-2b, and 210-3b. For example, each of the first to third pixel electrodes 210-1 to 210-3 may include triple layers including ITO/Ag/ITO layers.

According to an embodiment, like the pixel electrode, the first sensing electrode 210-4, the third sensing electrode 210-6, and the fourth sensing electrode 210-7 may include the transflective metal layers 210-4b, 210-6b, and 210-7b and the transparent conductive layers 210-4a, 210-4c, 210-6a, 210-6c, 210-7a, and 210-7c. That is, each of the first sensing electrode 210-4, the third sensing electrode 210-6, and the fourth sensing electrode 210-7 may include the transflective metal layers 210-4b, 210-6b, and 210-7b, the transparent conductive layers 210-4a, 210-6a, and 210-7a disposed below the transflective metal layers 210-4b, 210-6b, and 210-7b and the transparent conductive layers 210-4c, 210-6c, and 210-7c disposed above the transflective metal layers 210-4b, 210-6b, and 210-7b. For example, each of the first to third sensing electrodes 210-4, 210-6, and 210-7 may include a triple layer of ITO/Ag/ITO layers.

In contrast, the second sensing electrode 210-5 may further include the sub-sensing electrode 210-5s in addition to a main sensing electrode 210-5m. Like the pixel electrode, the main sensing electrode 210-5m may have a structure in which a transparent conductive layer 210-5a, a transflective metal layer 210-5b, and a transparent conductive layer 210-5c are sequentially stacked. For example, the main sensing electrode 210-5m may include triple layers of ITO/Ag/ITO layers.

That is, each of the first to fourth sensing electrodes 210-4 to 210-7 may include the transflective electrode, and thus, the first to fourth light-receiving devices PD1 to PD4 may form a cavity structure like the first to third light-emitting devices ED1 to ED3.

Here, according to an embodiment, the second sensing electrode 210-5 may further include the sub-sensing electrode 210-5s disposed above the main sensing electrode 210-5m. The sub-sensing electrode 210-5s may adjust an optical distance to cause the occurrence of optical microcavity in the light-receiving device PD. When the optical distance of the light-receiving device PD is optimized, light that is incident into the light-receiving device PD may have an increased intensity due to optical microcavity, and thus, light absorption by the first to fourth active layers 223-4 to 223-7 may be increased, and the efficiency of converting the absorbed light into currents may be increased.

Furthermore, the sub-sensing electrode 210-5s may increase a wavelength band of light which may be absorbed by the sensing area SA. As described above, when the first to fourth sensing electrodes 210-4 to 210-7 of the light-receiving device PD include the transflective electrodes, the light-receiving device PD may have a cavity structure, and thus, each of the light-receiving device PD may absorb only light of a single color. Here, the sub-sensing electrode 210-5s may adjust the optical distance such that the light that is incident into the corresponding light-receiving device PD may have a cavity, and thus, the sub-sensing electrode 210-5s may function such that the light that is incident into the corresponding light-receiving device PD may be absorbed by the first to fourth active layers 223-4 to 223-7. Accordingly, the light-receiving device PD may absorb light in a wavelength band varying according to a thickness of the sub-sensing electrode 210-5s, and thus, through the sub-sensing electrode 210-5s, the sensing area SA may absorb light in an increased wavelength band.

The sub-sensing electrode 210-5s may include a transparent conductive layer and may include TCO. For example, the sub-sensing electrode 210-5s may include ITO, IZO, AZO, In2O3, IGZO, ITZO, ZTO, FTO, GTO, GZO, ZnO, TiO, tungsten oxide, molybdenum oxide, or a combination thereof.

However, the disclosure is not limited to the sub-sensing electrode 210-5s only being included in the second sensing electrode 210-5. That is, the sub-sensing electrode 210-5s may also be disposed in the first sensing electrode 210-4, the third sensing electrode 210-6, and the fourth sensing electrode 210-7 according to a wavelength of light to be received by each light-receiving device PD.

Thus, a thickness of the sub-sensing electrode 210-5s may be determined according to the wavelength of light to be received. In an embodiment, a distance CD between the sensing electrode and the active layer in the light-receiving device PD may be approximately determined according to a cavity degree, a wavelength of light to be received, and a refractive index of a layer inbetween. In an embodiment, the distance CD between the sensing electrode and the active layer may increase, as the cavity degree increases. The distance CD between the sensing electrode and the active layer may be proportional to the wavelength of light to be received and inversely proportional to the refractive index of the layer inbetween. The distance CD between the sensing electrode and the active layer may include the first common layer 221, the second common layer 222, and the sub-sensing electrode 210-5s, and thus, a sum of thicknesses of the first common layer 221, the second common layer 222, and the sub-sensing electrode 210-5s may correspond to a primary cavity distance or a secondary cavity distance of light transmitted through the light-receiving color filter of each light-receiving device PD. That is, the thickness of the sub-sensing electrode 210-5s may increase or decrease according to the wavelength of light to be received.

According to an embodiment, the thickness of the sub-sensing electrode 210-5s may be about 250 Å to about 2000 Å. In an embodiment, when the sub-sensing electrode 210-5s is disposed in the first light-receiving device PD1 that receives red light, the thickness of the sub-sensing electrode 210-5s may be adjusted according to the primary cavity distance or the secondary cavity distance of red light. For example, the thickness of the sub-sensing electrode 210-5s disposed in the first light-receiving device PD1 may be about 600 Å to about 900 Å. Likewise, when the sub-sensing electrode 210-5s is disposed in the second light-receiving device PD2 that receives green light, the thickness of the sub-sensing electrode 210-5s may be adjusted according to the primary cavity distance or the secondary cavity distance of green light. For example, the thickness of the sub-sensing electrode 210-5s disposed in the second light-receiving device PD2 may be about 250 Å to about 500 Å. When the sub-sensing electrode 210-5s is disposed in the fourth light-receiving device PD4 that receives near-infrared light, the thickness of the sub-sensing electrode 210-5s may be adjusted according to the primary cavity distance or the secondary cavity distance of near-infrared light. For example, the thickness of the sub-sensing electrode 210-5s disposed in the fourth light-receiving device PD4 may be about 1300 Å to about 2000 Å.

According to an embodiment, at least one of the light-receiving devices PD may further include an optical auxiliary layer 223-4′. The optical auxiliary layer 223-4′ may adjust the optical distance for microcavity of the light-receiving device PD, like the optical auxiliary layers 223-1′, 223-2′, and 223-3′ of the light-emitting device ED. The optical auxiliary layer 223-4′ of the light-receiving device PD may be disposed on substantially the same layer as the optical auxiliary layers 223-1′, 223-2′, and 223e-3′ of the light-emitting device ED and may be disposed between the hole transport region and the first to fourth active layers 223-4, 223-5, 223-6, and 223-7. For example, the optical auxiliary layers 223-1′ to 223-3′ may be disposed between the second common layer 222 and the first active layer 223-4.

The optical auxiliary layer 223-4′ of the light-receiving device PD may have a thickness that is proportional to a wavelength of light to be received by the light-receiving device PD, like the optical auxiliary layers 223-1′ to 223-3′ of the light-emitting device ED. For example, the optical auxiliary layer 223-4′ of the first light-receiving device PD1 that receive red light of a wavelength of about 600 nm to about 650 nm may have a thickness of about 650 Å to about 900 Å.

By arranging the sub-sensing electrode 210-5s or the optical auxiliary layer 223-4′ in the light-receiving device PD as described above, in the display apparatus according to an embodiment, light of a different wavelength band may be absorbed by each light-receiving device PD. In an embodiment, the sub-sensing electrode 210-5s or the optical auxiliary layer 223-4′ may be disposed by adjusting thicknesses thereof according to a cavity distance of light transmitted through the first to fourth light-receiving color filters CF4 to CF7 disposed above the first to fourth light-receiving devices PD1 to PD4, respectively. Accordingly, while the high EQE may be maintained through the cavity structure of the sensing area SA, the light-receiving device PD may absorb light of an increased wavelength band, rather than light of a single color, and thus, may have increased light detection performance.

According to the display apparatus according to an embodiment as described above, the transparent conductive layer may be used, and thus, the light-receiving device may absorb light in an increased wavelength band and have increased detection performance.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display apparatus, comprising:
a substrate including an emission area and a sensing area;
a plurality of light-emitting devices disposed on the substrate and overlapping the emission area; and
a plurality of light-receiving devices disposed on the substrate and overlapping the sensing area,
wherein each of the plurality of light-emitting devices includes a pixel electrode, an emission layer disposed on the pixel electrode, and an opposite electrode disposed on the emission layer,
each of the plurality of light-receiving devices includes a sensing electrode, an active layer disposed on the sensing electrode, and an opposite electrode disposed on the active layer,
at least one of the plurality of sensing electrodes has a structure that is different from a stacked structure of the pixel electrode, and
the sensing electrode includes a first transparent conductive layer.

2. The display apparatus of claim 1, wherein the pixel electrode includes a transflective electrode including a second transparent conductive layer and a transflective metal layer.

3. The display apparatus of claim 2, wherein the transflective metal layer includes at least one of Ag, Al, Mg, Li, Ca, Cu, LiF/Ca, LiF/Al, MgAg, or CaAg.

4. The display apparatus of claim 1, wherein the sensing electrode includes a transparent electrode including the first transparent conductive layer, and
the first transparent conductive layer includes transparent conductive oxide (TCO).

5. The display apparatus of claim 4, wherein each of the plurality of light-receiving devices has a non-cavity structure.

6. The display apparatus of claim 4, wherein each of the plurality of sensing electrodes has a same thickness as each other.

7. The display apparatus of claim 1, wherein the plurality of light-receiving devices includes a first light-receiving device, a second light-receiving device, and a third light-receiving device spaced apart from each other.

8. The display apparatus of claim 7, wherein the active layer included in each of the first light-receiving device, the second light-receiving device, and the third light-receiving device includes a same material as each other.

9. The display apparatus of claim 7, further comprising:
a first light-receiving color filter disposed on the first light-receiving device;
a second light-receiving color filter disposed on the second light-receiving device; and
a third light-receiving color filter disposed on the third light-receiving device,
wherein the first light-receiving color filter, the second light-receiving color filter, and the third light-receiving color filter include different materials from each other.

10. The display apparatus of claim 9, wherein the first light-receiving color filter is a red color filter that transmits light of a wavelength band of about 600 nm to about 750 nm,
the second light-receiving color filter is a green color filter that transmits light of a wavelength band of about 495 nm to about 600 nm, and
the third light-receiving color filter is a blue color filter that transmits light of a wavelength band of about 380 nm to about 495 nm.

11. The display apparatus of claim 9, wherein the plurality of light-emitting devices include a first light-emitting device that emits red light, a second light-emitting device that emits green light, and a third light-emitting device that emits blue light,
a first color filter disposed on the first light-emitting device includes a same material as the first light-receiving color filter,
a second color filter disposed on the second light-emitting device includes a same material as the second light-receiving color filter, and
a third color filter disposed on the third light-emitting device includes a same material as the third light-receiving color filter.

12. The display apparatus of claim 7, further comprising:
a fourth light-receiving device spaced apart from the first light-receiving device, the second light-receiving device, and the third light-receiving device; and
a fourth light-receiving color filter disposed on the fourth light-receiving device.

13. The display apparatus of claim 12, wherein the fourth light-receiving color filter transmits near-infrared rays of a wavelength band of about 750 nm to about 1000 nm.

14. The display apparatus of claim 12, wherein the active layer included in the fourth light-receiving device includes a same material as the active layers included in the first light-receiving device, the second light-receiving device, and the third light-receiving device.

15. The display apparatus of claim 2, wherein at least one of the plurality of sensing electrodes includes a main sensing electrode and a sub-sensing electrode disposed on the main sensing electrode,
the main sensing electrode includes a same structure and a same material as the pixel electrode, and
the sub-sensing electrode includes a transparent electrode including a third transparent conductive layer.

16. The display apparatus of claim 15, wherein each of the plurality of light-receiving devices has a cavity structure.

17. The display apparatus of claim 15, wherein the sub-sensing electrode includes transparent conductive oxide (TCO).

18. The display apparatus of claim 15, wherein a thickness of the sub-sensing electrode is proportional to a wavelength of light transmitted by a light-receiving color filter disposed on each sensing electrode.

19. The display apparatus of claim 15, further comprising:
a common layer disposed between the sensing electrode and the active layer and between the pixel electrode and the emission layer.

20. The display apparatus of claim 19, wherein a sum of a thickness of the common layer and a thickness of the sub-sensing electrode corresponds to a primary cavity distance or a secondary cavity distance of light transmitted by a light-receiving color filter disposed on each sensing electrode.

21. The display apparatus of claim 19, further comprising:
an optical auxiliary layer disposed between the common layer and the active layer,
wherein a sum of a thickness of the common layer and a thickness of the optical auxiliary layer corresponds to a primary cavity distance or a secondary cavity distance of light transmitted by a light-receiving color filter disposed on each sensing electrode.
